(19) United States
(12) Patent Application Publication
(10) Pub. No.: US 2015/0218722 A1
(43) Pub. Date: Aug. 6, 2015

(54) MAGNETIC SHIELDING FOR MEASURING A PLURALITY OF INPUT AND/OR OUTPUT CURRENTS TO AN ELECTROLYTIC CELL

(71) Applicant: HATCH PTY LTD, Brisbane, QU (AU)

(72) Inventor: Jorge Garcés Baron, Santiago (CL)

(21) Appl. No.: 14/424,751

(22) PCT Filed: Aug. 26, 2013
(86) PCT No.: PCT/AU2013/000947

§ 371 Date: Feb. 27, 2015

Related U.S. Application Data
(60) Provisional application No. 61/694,211, filed on Aug. 28, 2012.

(51) Int. Cl. C25C 7/06; G01R 31/36

(52) U.S. Cl. CPC C25C 7/06; G01R 31/3606

(57) ABSTRACT

The present invention relates to a system and method for monitoring, in real time, the electric current that passes through each one of a plurality of single cathodes or anodes forming an electrolytic cell. The system comprises a plurality of sensor means including Hall Effect sensors. The sensor means are arranged for current measurement and thermal drift correction. Such sensors are located in a sensor bar which includes a protecting shield which provides magnetic shielding and also prevents corrosion. The present invention enables a more accurate measurement of the current of each electric unit within the electrolytic cell (cathode or anode) by using a ferromagnetic barrier acting as a magnetic shield in order to reduce the effects of magnetic fields adjacent to the target one and by correcting the measurement based on heat factors that may alter the measurement.

### FIELD OF APPLICATION

The present invention relates to a system for monitoring the electric current passingthrough an electrode or a plurality of electrodes within an electrolytic cell, comprising means for minimizing the effects that several types of variables have on current measurement, such as external magnetic field interference and temperature changes, in order to provide a reliable approximation of the current passing through each electrode.

The present invention can be particularly applied to real time monitoring of each cathode, or anode, constituting a metal electrowinning or electrorefining cell or other electrolytic cell with parallel electrodes.

### BACKGROUND

Metal extraction processes, such as those for copper, often include electrowinning or electrorefining recovery steps. With regard to these steps, it is important to monitor in real time each metal plate's performance in order to achieve an optimum performance of the electrolysis plants.

Within the electrolysis process, a short circuit may occur if electrodes are arranged misaligned, when due to physical flaws metal growth is not uniform on a surface, when higher than acceptable currents are applied or when an electrode is damaged. A low current situation may also occur when there is a poor electrical contact between anodes or cathodes and their current source, resulting in a reduction of the system efficiency. Both cases can lead to a low quality product, or in the case of copper electrorefining, the desired purity is not achieved and these factors can also lead to a reduction in current and power efficiency. Within this context, controlling the current that passes through the electrodes of each electrolysis unit is important to improve processes, products and efficiency using the aforementioned procedure.

The problem of monitoring each electrolysis unit is described in patent CL 44,909 (J. Garces Baron). In this patent, a monitoring system of the electric current passing through each cathode forming a set of electrodes is described, such monitoring system comprising a plurality of proximity electric current sensors connected to a communications means, and wherein such communication means communicates with a processing and control unit having graphical user interface means. Such proximity sensors measure the electric current passing through an electrode by measuring the strength of the magnetic flux density generated by such passing current.

In patent CL 44,909, the use of a method that enables optimization of current measurement in each cathode is not considered, nor the means for isolating the interference effects that the presence of adjacent plates or other variables may have on such measurement.

As it is widely known from the Biot-Savart Law, a current passing through a conductor generates a magnetic field which is proportional to the passing current and inversely proportional to the distance of the location thereof. The magnetic field generated by conductors, when the current passing through it is considered constant, is expressed in the following form:

$$B = \frac{{μ}_{0} i}{2 π R}$$

Where B is the electric field magnitude, μ₀ is the magnetic permeability of free space, i is the passing electric current, and R is the distance between the electrical conductor and the point of measurement. This form of the Biot-Savart law applies where the conductor can be considered to be infinitely long.

The magnetic field generated by one conductor may be detected by a sensor associated with another conductor. Thus, it is important to know the contribution of the adjacent cathodes (where cathode current is being measured) on which the measurement is to be carried out. For example, this problem is addressed in U.S. Pat. No. 7,445,696 (Eugene You et al.). This patent describes an apparatus and method for measuring current at each cathode, comprising one or more magnetic field sensors. Particularly, this patent describes a method that enables the differentiation among the magnetic field effects generated in adjacent cathodes on the cathode on which measurement is being carried out, by using several sensors that measure both the magnetic field contribution from the target cathode, and the field from adjacent cathodes, and then the collected data is processed with an algorithm taking into account several field contributions, thereby allowing a more accurate determination of the current at the cathode, ruling out interference from external sources.

Additionally, the main drawbacks of the aforementioned patent relate to the simplicity used to identify the interference generated by the electrodes adjacent to the one being measured, which is evidenced by the mathematical calculations carried out to determine the effects on the target electrode. Within this context, U.S. Pat. No. 7,445,696 does not describe a system which allows a reliable measurement of the electric current passing through an electrode, since it represents theoretical situations which, in practice, do not usually occur. Additionally, the solution proposed in said patent does not consider the external effects of the measurement, such as the effect of temperature which affects both the behaviour of magnetic fields and the electric current measured.

Thus, the invention described in the present application is intended to overcome the aforementioned problems of the prior art, by providing a reliable current measurement which enables optimizing processes in relation thereto, through a hardware reliable solution.

### SUMMARY OF THE INVENTION

The present invention relates to a system for monitoring, in real time, the electric current that passes through each one of a plurality of single cathodes or anodes forming an electrolytic cell. The system comprises a plurality of sensor means including Hall Effect sensors. The sensor means are arranged for current measurement and thermal drift correction. Such sensors are located in a sensor bar which includes a protecting shield which provides magnetic shielding and also prevents corrosion. Furthermore, such sensors are also in data-communication with central units, which preferably corresponds to at least one pre-processing unit, wherein such pre-processing units are in data-communication with a head controller unit which in turn is in data communication with the central server unit comprising a user interface.

The present invention also describes a method that enables a more accurate measurement of the current of each electric unit within the electrolytic cell (cathode or anode) by using a ferromagnetic barrier acting as a magnetic shield in order to reduce the effects of magnetic fields adjacent to the target one and by correcting the measurement based on heat factors that may alter the measurement.

### DESCRIPTION OF THE DRAWINGS

Further aspects of the invention will be better understood from the following detailed description of its preferred embodiments, given by way of example only, with reference to the accompanying drawings, in which:

FIGS. 1a, 1b and 1c depict an isometric view, an end view and a partial side view, respectively, of a first embodiment of the invention.

FIGS. 2a, 2b and 2c depict an isometric view, an end view and a partial side view, respectively, of a second embodiment of the invention.

FIG. 3 depicts a diagram in which is carried out a vector analysis over the sensor “j” of the sensor bar.

FIG. 4, depicts a general schematic view of the components in order to explain their connections.

### DESCRIPTION OF A PREFERRED EMBODIMENT

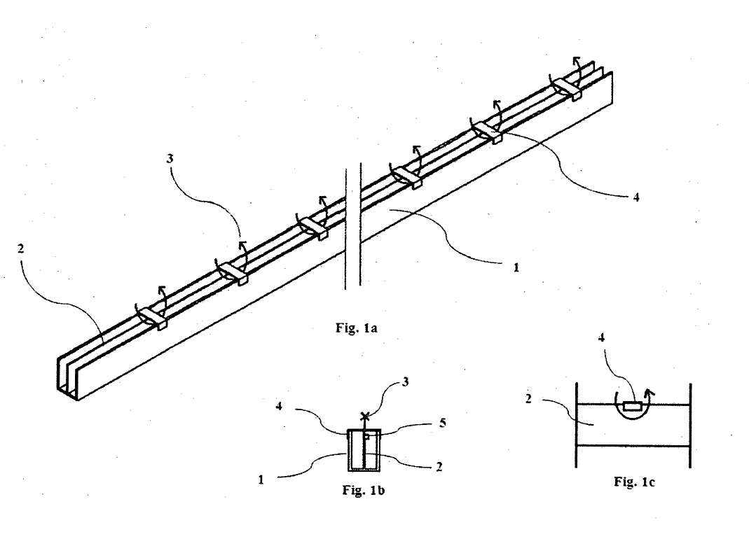

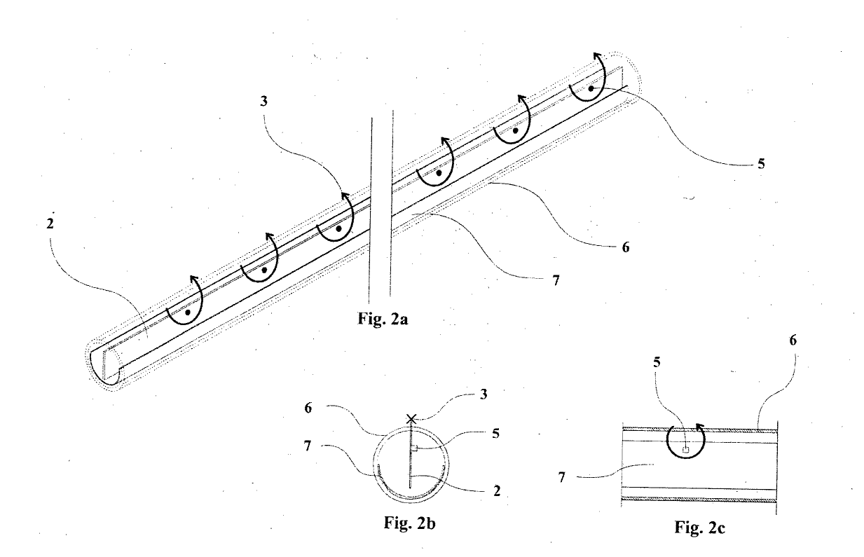

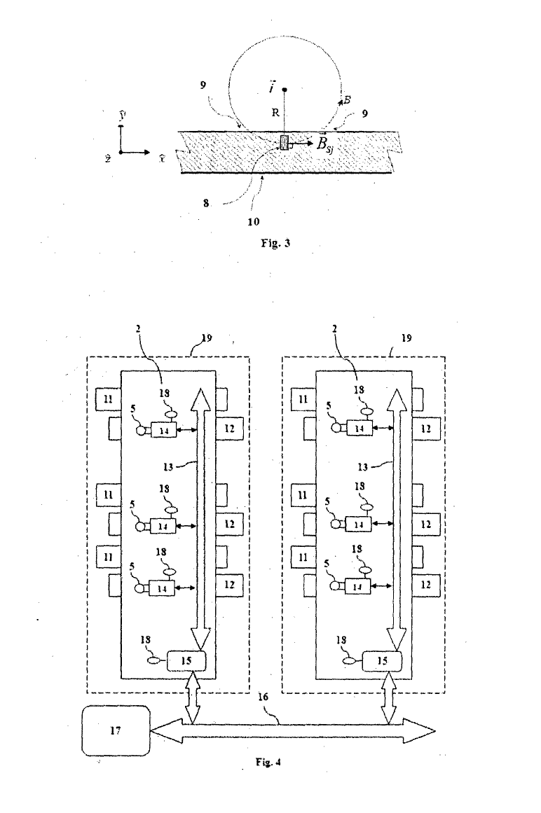

The preferred embodiments of the present invention will now be described, being illustrated in FIGS. 1a, 1b, 1c, 2a, 2b and 2c, the operation of which is depicted in the scheme of FIG. 3. Additionally, the components referred to in FIG. 4 are used to determine their interaction within the system.

The system of the invention comprises an electrolysis cell (19) comprising a plurality of cathodes (12) and anodes (11), arranged in an alternating manner relative to each other. In the case of the invention, cathodes (12) and anodes (11) correspond to plates which are arranged parallel to each other. In the vicinity of each plate, preferably, of each one of the cathode plates, sensor means (5) are arranged on a sensor bar (2). Such sensor bar is located in the vicinity of the current output (or input) bar from (or to) the cathode (or anode) plate. Such sensor bar and such sensor means are not in direct contact with the electrodes.

In a preferred embodiment the sensor means. (5) are connected with pre-processing units (14) in order to improve the quality of the signal and to facilitate it reading and interpretation in the following units of the system, preferably such pre-processing unit (14) is a microprocessor unit. Then, it may be possible for each individual sensor unit (which comprises one or more sensor devices (5) and a pre-processor unit (14)) to communicate directly with the central server unit. However, is preferable to have individual sensors within one sensor bar communicate data to a single head controller unit in that bar. The head controller unit (15) can then communicate the whole bar's data to the central server unit (17). If communication to the central server unit (17) is wireless (e.g. Wi-Fi), then this would reduce the number of relatively expensive wireless interfaces by a factor of approximately 60. Other parts of the sensor circuits that can be shared, such as voltage regulators, may also be located in the head controller unit (15) for cost advantages. Finally, in a preferred embodiment of the invention it is useful to have a central location at which all the electrode currents can be monitored. This helps an operator to see immediately which electrode in which cell may have either a low current or a high current, and therefore to rectify the condition quickly. Information can be transmitted from each cell (typically, but not necessarily from the head controller unit—it could be from every sensor) to a central computing device where the information is displayed.

If the information is received by a central computing device for display, it can also be stored for further subsequent analysis. This analysis can provide historical trend information which can help the operator to identify sources of variance which reduce overall manufacturing quality. By detecting when cell deposition cycles commence (by detecting the removal of one-third of the electrodes at stripping time), it can also help the operator to identify when a given electrode (and hence cell) has passed enough charge (amp-hours) to be ready for stripping. The system can maintain a table showing the preferred order in which cells should be stripped. The system can also tell how long it has been since a cell was cleaned, and hence provide a recommendation for the time and order for cells to be cleaned.

Preferably, each one of the sensor means (5) is in data-communication with the corresponding pre-processing unit (14), which in turn is in data-communication with a communication channel, such as a sensor data bus (13), whose signals are received by a head controller unit (15), located in each one of sensor bars (2). The above mentioned data communication may be achieved through many different means including optical, cable or bus. Additionally, signals from each head controller unit (15) are received by a communication channel, which may be a main data bus (16), which is in data-communication with a central server unit (17). The main function of this head controller unit (15) is to control communications between the central server unit (17) and each one of the pre-processing units (14).

Preferably, data communication between the pre-processor units (14) and the head controller unit (15) is carried out through wireless communication. In this way, “noise” that may be generated by crowded wiring within the area of measurement is eliminated, especially in areas close to sensors. Communication between the head controller unit and the central server unit is preferably also wireless.

The sensor means (5) comprise electric current sensors, means for measuring the effect of temperature on the current measurement, and any other type of sensor used for measuring the behaviour of the process and electrodes within the electrolytic cell. Preferably, electric current sensors are magnetic sensors, known as Hall Effect sensors, or any other sensor having a calibratable response within the operating range of electrolytic cells (19). In one embodiment of the invention is possible to include other types of sensors to monitor the condition of each individual cell for electrolyte temperature.

Additionally, in order to be protected, sensors means (5), and preferably the pre-processing units (14), are encapsulated in a corrosion resistant material housing (1, 6). This encapsulation is part of the aforementioned sensor bar (2).

Additionally, magnetic shielding (10) is included, which reduces the impact of the magnetic fields (3) generated by conductors surrounding the unit to be measured, which allows reduction of measurement interference, thus getting more accurate data.

Particularly, this shielding (10), which affects the magnetic field from particular sources, comprises a coating over the largest part of the sensor bar (2) surface, this coating being made of a high magnetic susceptibility material, implying a high magnetic permeability of the material. Inside the sensor bar (2) there are unshielded areas or so called magnetic field penetration windows (9), which correspond to windows wherein sensor means are arranged in a particular orientation. In an embodiment of the invention (FIG. 1a), the magnetic shielding (10) corresponds to ferromagnetic plates (1, 4) protecting and surrounding, in a particular configuration, the sensor used in the invention, wherein said configuration determines that certain field lines (3) are to be detected by sensors, while the arrangement of the plates (4) acts as a shield over other field lines. In another embodiment of the invention (FIG. 2), the magnetic shielding (10) comprises a coating applied to the shielding device (6) covering the sensor bar (2), wherein said coating may contain ferromagnetic particles (7), for instance, a ferromagnetic paint or tape containing iron, nickel or cobalt fines. Consequently, multiple different methods of providing shielding can be used in the invention, this may include the use of a paint containing ferromagnetic particles (as already described), or similar particles embedded in a rubberized material that may have adhesive back, sheets of ferromagnetic material (iron, Ni, Co etc), a coating which may be any substrate that contains ferromagnetic particles that could be coated onto the housing or any non-ferromagnetic material which use is comparable to the above mentioned ferromagnetic materials.

FIG. 3 depicts a scheme of the invention, which illustrates the vector decomposition of the magnetic field \vec{B} acting over the sensor “j” (8), which is located at a distance R from the current conductor generated by said magnetic field \vec{B} due to the passage of a current \vec{i} in direction \vec{z}. Said sensor is surrounded by a magnetic shield (10), with a high magnetic susceptibility. The magnetic field induced at a distance R from the magnitude current conductor i enters through the field penetration windows (9), allowing the magnetic field \vec{B}ₛⱼ, to act over the sensor “j” (8), and said field being defined by the magnitude B acting in direction \hat{x}. In this sense, magnitude B can be calculated by a mathematical equation to obtain the magnetic field generated by the current passing through a linear conductor, said equation being:

$$B = \frac{{μ}_{0} i}{2 π R}$$

wherein μ₀ is the magnetic constant or magnetic permeability in free space.

Then, the above mentioned shielding (10) and devices improve the current measurement, which result in a more efficient control process. Accordingly, central server unit (17) comprises graphical user interface means, so that the user can enter the desired control parameters, such as lower threshold current values Iₘᵢₙ and upper threshold current Iₘₐₓ, while this central server unit (17) updates and stores readings of each cathode current (12) from sensor means (5) which are protected by the aforementioned shielding device (6), previously noise-filtered by using the pre-processing units (14), wherein the corresponding corrections to the effects on the current measurement of other type of variable such as temperature are also made.

In this context, the techniques described above can be combined in different ways and similar techniques can compensate for other environmental variables apart from temperatures, for example the supply voltages or RF interference.

The state of each electric unit, particularly, of each cathode with regard to pre-established threshold values, may correspond to any of the following three states:
(a) Current below lower threshold, or a situation of cathode isolation or high contact resistance.
(b) Current between lower and upper thresholds, or a situation of cathode normal functioning; or
(c) Current above the upper threshold, or a situation of over current.

For the above described states it can be useful to provide a tracking system for the total charge passed through a particular electrode during a deposition cycle, and to compare this against the mass of the product that is eventually stripped from the electrode. This comparison yields the current efficiency of the electrode, which is traditionally only able to be calculated as an aggregate across the whole tankhouse across long time periods. But detecting problems with individual electrodes (such as poor contacts due to miss-shaped header bars), or individual cell locations (such as poor contacts due to miss-shaped bus bars) would be desirable. This means that is necessary to record the charge for a given electrode, and track the mass of the produce from that same electrode. This requires the ability to identify a specific electrode. Recall that a given electrode may be used in different positions in different cells throughout its life

In this context, a typical approach to identify a specific electrode involves operators with IR-cameras having to walk around continuously, being useful to include an indication of where these faults are located. Therefore, in a preferred embodiment within each pre-processing unit (14) as well as within each head controller unit (15) cathode state and cell state indicators (18) are provided, which in a preferred embodiment of the present invention can be luminous indicators such LEDs, with several colours, associated to each one of the aforementioned cathode functioning states. Consequently, besides an indication of the cathode state which may be displayed on a screen of the central server unit (17), a local visual indication for each cathode is generated through cathode state indicators (18), and in front of each electrolytic cell (19), through cell state indicators (18).

In the case of the cell state indication, the indication strategy of the aforementioned embodiment consists of:
“Normal cathode” indication, if every cathode is under this normal condition; or
“Low current” indication, if at least one of the cathodes is under this condition (low current) and the rest of the cathodes are under normal conditions (one activated colour); or
“High current” indication, if at least one of the cathodes is in this condition (high current) one activated colour; or finally
“Low current and high current” indication, if the current in one or more cathodes is below the lower threshold, and also if the current in one or more cathodes is above the upper threshold (two activated colours).

Once main components of the present invention have been defined, considering both the components from prior art and the ones being the subject matter of the present patent application, it is possible to define the method used by the novel current measurement system.

As stated above, the method of the present invention consists of measuring the desired variables through sensor means (5), wherein signals generated by current sensor means and thermal drift means enter into a unit (14), wherein said current sensor means (5) are preferably composed of pairs of magnetic detectors or Hall effect sensors arranged back-to-back. In order to explain this kind of arrangement it might be considered the outputs from the two hall sensors Vh1, Vh2 as the sum of a quiescent (no field) voltage, Vq, component due to temperature effect Vt, and a component due to magnetic flux effect Vm. That is, Vh1=Vq1+Vt1+Vm1, and Vh2=Vq2+Vt2+Vm2. The two hall sensors will experience the same quiescent and temperature effects (Vq1=Vq2, and Vt1=Vt2, at least to a first order approximation), but the polarity of the magnetic effect will be opposite (Vm1=−Vm2). The difference between the outputs of the hall sensors will be Vh1−Vh2=Vq1−Vq2+Vt1−Vt2+Vm1−Vm2=2×Vm1. Thus the “signal” is amplified, and the “noise” is attenuated. Each one of these magnetic detectors generates a corresponding output signal, which is proportional to the magnetic field where the detector is immersed. Magnetic shield (10) reduces the magnetic flux produced from neighbouring conductors in the vicinity of the sensor. This ensures that output from the sensor closely corresponds with the magnetic flux (3) produced by the local conductor. The shield may include “windows” or unshielded zones (9). The shield geometry is carefully arranged to maximize magnetic flux (3) of the local conductor reaching the sensor (5) and to minimize the magnetic flux of non-local conductors reaching the sensors.

The voltage output from the magnetic field sensor can be converted into a current measurement by a transformation. This transformation can be performed by analog electronics (such as operational amplifiers configured in various ways) or digital electronics (such as programmable microprocessors, either in the pre-processing unit or a central server), or a combination of the two methods. In a preferred embodiment, the voltage Vm from the magnetic field sensor is able to be converted into a digital form Nm1 by the pre-processor, and also the difference between the voltage Vm and a reference voltage Vr can be amplified by a differential operational amplifier to make Va=g×(Vm−Vr)+c, which is then converted into a digital form Nm2 by the pre-processor. The pre-processor software can select Nm1 for further transformation if the field is strong and Nm2 if the field is weaker. The whole arrangement can be repeated for a second magnetic field sensor in reverse orientation.

In an embodiment of the invention, compensation of the current measurement is carried out. In this context, one technique involves using a single hall sensor and a separate temperature sensor. If the effect of temperature on the hall devices can be characterized, either using data from the hall device manufacturer, experimentation, or calibration, then this effect can be removed from the signal. This compensation may be performed while the signal is in analog form, or after it has been converted to a digital value. Also, it may be performed in the vicinity of the sensor device itself, by a pre-processing unit (14), by a head controller unit (15), or by a central server unit (17). This kind of mechanism allows compensating for non-linear effects.

Additionally, in an embodiment is possible to use analog compensation that may be applied as follows. It may be desirable to amplify the output from a single hall sensor. But since the zero-field (quiescent) output from the sensor is non-zero, it is necessary to amplify the difference between the output and a reference signal. This could be performed using an operational amplifier. The reference signal could be a constant voltage, obtained by a resistor divider network, or other voltage reference. Or for more sophisticated compensation, a reference voltage could be created that is dependent on the temperature. This could be achieved by using a temperature sensor whose output is digitized and transmitted to a microprocessor. The microprocessor could perform the appropriate calculations, and then use a digital to analog converter to create the appropriate reference voltage for the measured temperature.

According to the method, in a preferred embodiment the pre-processing unit (14) receive the data from the sensor units and performs corrections to the data signal in order to provide an optimal signal transmission through the data communication channel to the following units and corrections to the current measurement caused by the effect of external variables such as temperature, for which the above mentioned compensations can be carried out based on temperature rise and on magnetic field fluctuations. In a further embodiment of the invention, such compensations are assisted by temperature sensor means which directly measure the state thereof to perform corrections to current measurement.

Additionally, the pre-processing unit (14) comprises gain control means, which regulate the signal intensity entering into the operational amplifier, based on a pre-established cell current level. The pre-processing unit (14) also comprises calibration means, which allow offsetting of input signals to the operational amplifier so that when under known calibration conditions, with cathode current being null, this signal is also null. In this context, is preferable to compensate for any minor variations in the system. This may include effects of the power supply, temperature, manufacturing tolerances in the Hall Effect sensors or any other parts of the circuit, physical proximity of the Hall sensor to the device, effects due to stray currents, effects due to the shielding, or any other effects that may be compensated by calibration. The calibration activities may take place in different steps. For example, some effects may be calibrated in the factory, and others once the device is installed in the tankhouse. Calibration may involve the use of additional components of the overall system, including an ammeter (typically using a clamp), and possibly a portable computing device (such as a laptop or tablet) which an operator can carry around during in-tankhouse calibration activities.

Then, the measured currents are compared with the lower threshold current and upper threshold current Iₘₐₓ, pre-established for the entire system, thus determining the state of the present reading and activating a cathode state indicator (18), which can be interpreted by an operator of the electrolytic plant. In a preferred embodiment of the method this indication can be interpreted from the information displayed on a central control panel or from the information displayed on a portable computing device, wherein all the possible information means include the state of all the electrolytic devices or an interpretative summary of the main units.

In a preferred embodiment, calibration activities are assisted by using a portable computing device such as a tablet, and an ammeter that can communicate to the portable computing device or central server by wireless communications. This will minimize the disruption that such activities cause to plant operations, and minimize their duration and the effort involved.

1. A monitoring system for monitoring the electric current circulating through each one of a plurality of single electric units constituting an electrolytic cell; the system comprising current sensors, processing units and built-in data transport means to provide a reliable and meaningful measurement of the current circulating through each one of the electrodes, wherein
a. such current sensors are located by a magnetic shielding device covering it of the magnetic field generated by adjacent electrode current circulation; and
b. such processing units comprise means for correcting the measurement of the current circulating through each one of the electrodes based on the effects external variables have on magnetic field behaviour.

2. Monitoring system according to claim 1, wherein the magnetic shielding device blocks specific magnetic fields generated by adjacent electrodes, allowing “only” certain magnetic field sources to be detected by current sensors.

3. (canceled)

4. Monitoring system according to claim 1, wherein the shielding device comprises a coating or otherwise shielding over the largest part of the sensor bar surface.

5. (canceled)

6. (canceled)

7. (canceled)

8. (canceled)

9. (canceled)

10. (canceled)

11. (canceled)

12. Monitoring system according to claim 1, wherein the shielding device provides protection against corrosion.

13. Monitoring system according to claim 1, wherein the processing unit compensates the current measurement based on the effects that temperature generates over the current sensors.

14. Monitoring system according to claim 13, wherein current compensation based on temperature is performed by measuring through sensors the actual temperature of the electric units.

15. (canceled)

16. Monitoring system according to claim 1, wherein the sensor means correspond to Hall Effect sensors.

17. (canceled)

18. Monitoring system according to claim 20, wherein the Hall Effect sensors are arranged back-to-back to provide temperature compensation for the current measurement.

19. (canceled)

20. Monitoring system according to claim 1, wherein the data-communication channel corresponds to a wireless communication.

21. A monitoring method for monitoring the electric current circulating through each one of the plurality of single electric units constituting an electrolytic cell, comprising current sensors, processing units and built-in data transport means to provide a reliable and meaningful measurement of the current circulating through each one of the electrodes, wherein such method comprises the stages of:
a. Protecting current sensors against magnetic fields generated by adjacent electrodes, by using a magnetic shielding device covering sensors.
b. Correcting current measurement due to external variables affecting the measurement thereof, by using a processing unit which processes the effects such variables have on magnetic field behaviour.
c. Sending by means of a data communication channel the information from each processing unit to a controller head unit located at each electrolytic cell.
d. Sending by means of a data communication channel the information from each controller head unit to a control and processing master station.

22. Monitoring method according to claim 21, wherein the magnetic shielding used at the current sensor protection stage blocks specific magnetic fields generated by adjacent electrodes, allowing certain magnetic field sources to be detected by current sensors.

23. (canceled)

24. Monitoring method according to claim 21, wherein the shielding device used at the current sensor protection stage comprises a coating over the largest part of the sensor bar surface.

25. (canceled)

26. (canceled)

27. (canceled)

28. (canceled)

29. (canceled)

30. (canceled)

31. (canceled)

32. Monitoring method according to claim 21, wherein the shielding device used at the current sensor protection stage further provides protection against corrosion.

33. Monitoring method according to claim 21, wherein the processing unit used at the current measurement correction stage is based on the effects temperature generates on the magnetic field behaviour and thus, the measured electric current.

34. Monitoring method according to claim 21, wherein the correction stage is carried out by measuring through sensors the actual temperature of the electric units.

35. Monitoring method according to claim 21, wherein the current correction stage is carried out by mathematically combining the outputs of the Hall Effect sensors.
